(19) United States
(12) Patent Application Publication
(10) Pub. No.: US 2005/0147920 A1
(43) Pub. Date: Jul. 7, 2005

(54) Method and system for immersion lithography

(76) Inventors: Chia-Hui Lin, Hsin-Chu (TW); Yee-Chia Yeo, Singapore (SG)

Correspondence Address: DUANE MORRIS, LLP;IP DEPARTMENT, ONE LIBERTY PLACE, PHILADELPHIA, PA, 19103-7396, US

(21) Appl. No.: 10/748,076

(22) Filed: Dec. 30, 2003

(51) Int. Cl. G03B 27/00; G03F 7/00; G03F 7/20

(52) U.S. Cl. 430/311; 430/313; 355/18

(57) ABSTRACT

A system (100) and method for immersion lithography is disclosed in which an immersion medium (112) interfaces with a proximal lens (110) that focuses a patterned light beam on a light sensitive material (116), wherein the light sensitive material (116) is covered by a protective film (300) that interfaces with the immersion medium (112).

### FIELD OF THE INVENTION

The present invention relates to immersion lithography, and more particularly, to protection of a workpiece from an immersion medium of an immersion lithography system.

### BACKGROUND

A conventional lithography system has a light source, a first lens, an opaque patterned mask, a final lens or proximal lens, and a light or radiation sensitive material, for example, a photoresist (PR) or other photo or light sensitive material, to be patterned by the lithography system.

The first lens receives incident light and transmits a directed light beam through patterned openings extending through the opaque patterned mask to produce a patterned light beam. An imaging module or imaging system has a final lens, or proximal lens, which focuses the patterned light beam on the surface of the workpiece, for example, a PR for semiconductor processing of a semiconductor substrate. A semiconductor substrate is in the form of a base semiconductor wafer or other type of base member to have one or more layers of patterned, semiconductor elements or features. The pattern of features are first formed in the PR by the lithography system. The PR is patterned by the lithography system to define a pattern of miniature and sub-miniature semiconductor features to be etched into the top layer of the substrate. Lithography is the preferred process of producing the patterned PR with miniature and subminiature sized features.

The semiconductor processing industry continues to develop ever smaller semiconductor features. New developments in ultra violet wavelength light sources, and new developments in substrate materials having anti-reflective/anti refractive properties and high dielectric constants continue to advance further reductions in line width and feature size.

However, reductions in line width and feature size are limited by the image resolution of a lithography system. For a conventional lithography system, the patterned beam transmits in atmospheric air, which limits the lithography system to have a numerical aperture, NA, no greater than 1. Resolution enhancement would be obtained by using a transmission medium with a refractive index of larger than 1 to interface with the proximal lens. This would allow the achievement of a NA greater than 1.

Immersion lithography offers better resolution enhancement than conventional lithography. U.S. 2002/0163629A1 discloses an immersion lithography system. In immersion lithography, a substrate to be patterned is immersed in a high index fluid, i.e., an immersion medium, with an index (n>1), such that the high index fluid is the beam transmission medium. The beam transmission medium or immersion medium fills the space between the final optical element or lens and the substrate. The high index is matched by a final or optimal lens that can have a numerical aperture greater than 1 to improve image resolution.

The known immersion mediums include, perfluoropolyether, PFPE, cyclo-octane and de-ionized water, DI water. In an immersion lithography system, the immersion medium is in contact with the PR surface that can be formed by different resist materials. Any new immersion medium must undergo extensive tests to satisfy several requirements. It would have a low absorption of electromagnetic radiation or light. Its index (refraction index) would be high relative to that of prior immersion materials to justify the expense of testing for compatibility. The medium would be inactive or benign to interaction with the resist system and the lithography system in a manner that would impede image formation. For example, the medium would avoid physical alteration of the substrate surface topography and the proximal lens. The medium would be chemically non-reactive with materials of the resist system and lithography system. The medium would be non invasive of a clean room environment, and non-invasive of other processes for substrate manufacturing.

The known immersion mediums have passed extensive testing for compatibility with the resist system and the lithography system. However, on-going research continues to discover new resist systems. Accordingly, both existing and new immersion mediums need to be tested for compatibility with the new resist systems. A continuing need for increased resolution of smaller line widths will continue to drive research seeking new immersion mediums with ever increasing indices.

Prior to the invention, implementing either a new immersion medium or a new PR for an immersion lithography system was delayed until completion of compatibility testing between the PR and the immersion medium.

### SUMMARY OF THE INVENTION

The invention is an immersion lithography system that advantageously permits the use of new immersion mediums and new photosensitive or photoresist (PR) materials. The invention provides a protective film overlying a PR material to prevent interaction between the immersion medium and the PR material.

In one example, after forming a light sensitive material on a substrate, a protective film is formed over the light sensitive material to seal it thereunder. The light sensitive material sealed by the protective film is subject to an immersion lithography system for creating a pattern on the light sensitive material, wherein the protective film seals the light sensitive material from an immersion medium used by the immersion lithography system.

### BRIEF DESCRIPTION OF THE DRAWINGS

FIG. 1 is a diagrammatic view of an immersion lithography system.

FIG. 2 is a diagrammatic view of a portion of an immersion lithography system.

FIG. 3 is a diagrammatic view of a portion of an immersion lithography system according to one example of the invention.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,”etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

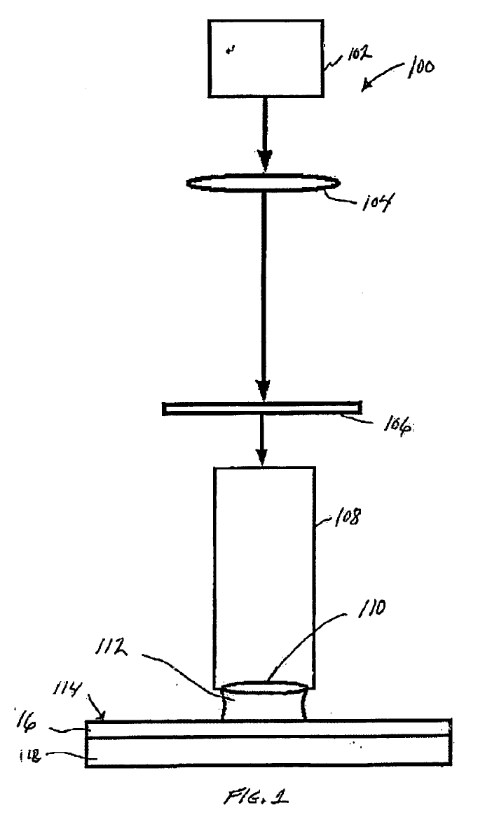

FIG. 1 discloses an immersion lithography system (100) that has an electromagnetic radiation such as a light source (102). The source (102) produces single wavelength light or, according to an interference light source (102), the source (102) produces a light beam formed by an interfering pattern of two or more light beams. The light beam is incident on a lens (104) that directs a directed light beam through a patterned opaque mask (106) producing a patterned light beam. The system (100) has, an imaging module (108) having a final lens (110) or proximal end (110) and an index matching medium (112) displacing air between the proximal end (110) and a workpiece (114). For example, the workpiece (114) is a light sensitive material (116), including, but not limited to, a photo resist, PR, to be optically imprinted with a lithographic pattern for semiconductor processing. The light sensitive material (116) covers a semiconductor substrate (118) formed by one or more material layers that are built up on a semiconductor wafer or other base circuit interconnect member.

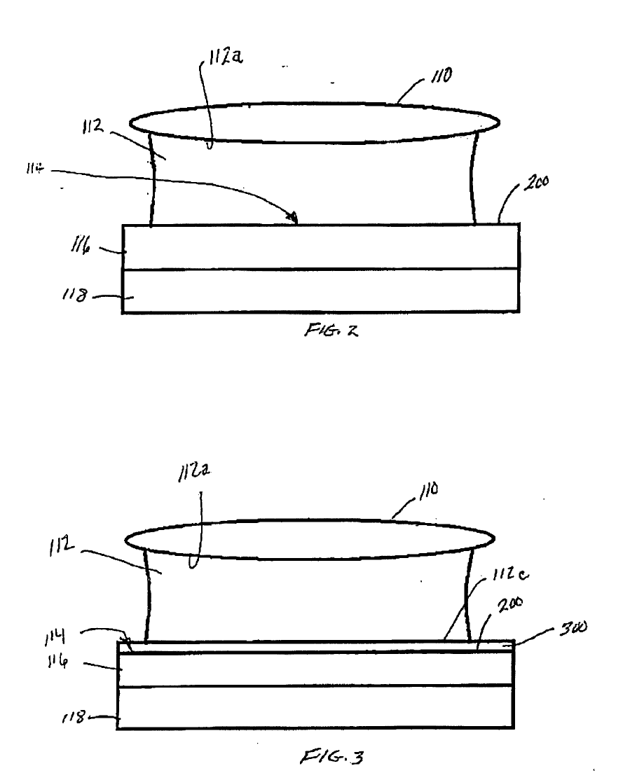

FIG. 2 discloses the surface (200) of the light sensitive material (116), e.g., part of the workpiece (114), being illuminated with a patterned light beam transmitting through the immersion medium (112) having interfaces (112a) and (112b) with other materials (110) and (116). [Reference numeral 112b is not depicted in FIG. 2.] The immersion medium (112) has an index, n, that substantially matches the indices of the other materials, such as proximal end (110) of imaging module (108) and light sensitive material (116) to transmit the light radiation through the interfaces (112a) and (112b) without significant refraction or reflection of the light radiation.

According to an embodiment of the invention, FIG. 3 discloses a protective film or protection layer (300) that is substantially impermeable by the immersion medium (112). The protective film (300) covers the surface (200) of the light sensitive material (116). In turn, the light sensitive material (116) covers the semiconductor substrate (118). The protective film (300) and the immersion medium (112) have nearly matching indices at the interface (112c), with a capability of distinguishing a minimum line width nearly equal to the light wavelength of the light beam. A pattern of fine line widths corresponds to fine line width elements of a semiconductor integrated circuit being fabricated in the material layers of the substrate (118).

An embodiment of the protective film (300) is impermeable to outgases of the light sensitive material (116) and other material layers of the substrate (118) to avoid bubble formation in the immersion medium (112). Bubbles are known to scatter light, and bubble formation in the immersion medium potentially interferes with the accurate transfer of a patterned beam onto the light sensitive material (116). Effectively, the protective film functions like a sealing layer that seals the light sensitive material (and any other material layer beneath) from the immersion medium.

The protective film (300) is compatible, i.e., nonreactive and benign of chemical reaction with the light sensitive material (116). The light sensitive material (116) may be formed by various materials, and is typically found to be one of the following materials such as for example, acetal, methacrylate, polymer or hybrid or combinations thereof. The selected protective film (300) needs to be compatible with a selected light sensitive material, without having to be compatible with all other materials.

The thickness of the protective film (300) is irregular or, alternatively, is of uniform thickness, as long as it is sufficiently thick to maintain a continuous barrier between the light sensitive material (116) to be patterned and the immersion medium (112). The surface topography of the protective film (300) that interfaces with the immersion medium (112) can be concave, piano, diffractive, and have other surface roughness and step height variations due to imbedded patterned structures from previous lithography operations performed on inner layers. The immersion medium (112) is of fluid phase to interface continuously with the step height irregularities in the surface of the protective film (300), which will counteract light beam backscatter and light diffraction at the interface (112c).

The protective film (300) may be of solid phase (but can be of other more flexible forms), and is benign to physical and chemical interaction with the solid light sensitive material (116). The immersion medium (112) of fluid phase is likely to be a solvent of the light sensitive material (116). However, the light sensitive material (116) is covered and protected by the protective film (300). According to an embodiment of the invention, the protective film (300) has a zero dissolution rate in the immersion medium (112). According to another embodiment of the invention, the protective film (300) has a slow dissolution rate in the immersion medium (112). The thickness of the protective film (300) exceeds the thickness etched by slow dissolution in the immersion medium (112) while photo-patterning the light sensitive material (116).

A protective film (300) may also conform to the topography of the underlying light sensitive material (116) so that the light sensitive material is well sealed thereunder. An embodiment of the conformal protective film (300) has an irregular topography that follows the irregular topography of the underlying light sensitive material (116).

In another example, if needed, the protective film (300) can have a topography that is planarized, for example, by performing a chemical mechanical planarization, CMP, on the surface of the protective film (300). The planarized protective film (300) has a thickness that exceeds the step height difference in the underlying light sensitive material surface topography, while a planarized surface on the planarized protective film (300) registers evenly with the patterned image of the patterned beam.

The protective film (300) covers a light sensitive material (116) whether it has an irregular topography, or, alternatively, a planarized topography that is smooth, planar and polished, without significant topography step height and surface roughness. The protective film (300) is a temporary film and is removed after photo patterning of the light sensitive material (116) by the immersion lithography system (100). While removing the protective film, a two-step approach can be taken in which the protective film is first removed, and the photoresist material sealed thereunder is now exposed. Regular etching methods can be applied to further etch off undesired portions of the photoresist material. In another example, a selective chemical is used which can in one step etch off both the protective film as well as the undesired portion of the photoresist material.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. An immersion lithography system, comprising:
a light source; and
an imaging module projecting a pattern onto a light sensitive material, the light sensitive material covered by an overlying protective film and immersed in an immersion medium,
wherein the protective film does not interfere with the imaging module and light source for projecting the pattern on the light sensitive material through the immersion medium.

2. The immersion lithography system as in claim 1 wherein said protective film being impermeable of outgases from the light sensitive material.

3. The immersion lithography system as in claim 1 wherein said protective film and the immersion medium have nearly matching indices of refraction.

4. The immersion lithography system as in claim 1 wherein said protective film is of irregular thickness.

5. The immersion lithography system as in claim 1 wherein said protective film has a planarized surface.

6. The immersion lithography system as in claim 1 wherein said protective film is non reactive and benign of physical and chemical interaction with the light sensitive material.

7. The immersion lithography system as in claim 1 wherein said protective film is light sensitive.

8. The immersion lithography system as in claim 1 wherein said protective film is compatible with acetal or methacrylate based polymer or hybrid material.

9. The immersion lithography system as in claim 1 wherein said protective film has a predetermined thickness with which a dissolution of the protective film by the immersion medium during projecting does not impact the protective film for sealing the light sensitive material thereunder.

10. The immersion lithography system as in claim 1 wherein said protective film has a thickness of less than 1000 Angstroms.

11. A method for patterning a light sensitive material, comprising the steps of:
forming a light sensitive material on a substrate;
forming a protective film over the light sensitive material to substantially seal it thereunder; and
subjecting the light sensitive material sealed by the protective film to an immersion lithography system for creating a pattern on the light sensitive material,
wherein the protective film seals the light sensitive material from an immersion medium used by the immersion lithography system.

12. The method of claim 11 wherein the subjecting further includes:
directing an electromagnetic beam through a patterned mask to the immersion medium; and
focusing the beam through the immersion medium and on the light sensitive material.

13. The method of claim 11 further comprising planarizing the protective film prior to focusing the beam.

14. The method of claim 11 further comprising removing the protective film to expose at least a portion of the light sensitive material.

15. The method of claim 14 wherein the removing further includes:
removing the protective film to expose the light sensitive material; and
removing undesired portions of the light sensitive material according to the pattern created.

16. The method of claim 14 wherein the removing further includes removing the protective film along with undesired portions of the light sensitive material according to the pattern created.

17. The method of claim 11 wherein the protective film has an uneven surface with step height variations.

18. The method of claim 11 wherein the protective film has a thickness of less than 1000 Angstroms.

19. The method of claim 11 wherein the protective film has a thickness that exceeds the thickness etched by its dissolution in the immersion medium.

20. The method of claim 11 wherein the protective film is not dissolvable in the immersion medium.

21. A method of fabricating elements of a semiconductor integrated circuit comprising the steps of:
forming a photoresist material on a substrate;
forming a protective film over the photoresist material to substantially seal it thereunder;
directing a light source through a patterned mask to create a patterned beam;
focusing the patterned beam on a predetermined area of the photoresist material; and
interfacing an immersion medium with at least a lens that focuses the patterned beam on the photoresist material,
wherein a pattern is created on the photoresist material through the protective film by the patterned beam.

22. The method of claim 21 wherein the protective film has a thickness that exceeds the thickness etched by its dissolution in the immersion medium.

23. The method of claim 21 wherein the protective film is planarized.

24. The method of claim 21 further comprising removing the protective film to expose at least a portion of the photoresist material.

25. The method of claim 24 wherein the removing further includes:
removing the protective film to expose the photoresist material; and
removing undesired portions of the photoresist material according to the pattern created.

26. The method of claim 24 wherein the removing further includes removing the protective film along with undesired portions of the photoresist material according to the pattern created.

27. The method of claim 21 wherein the protective film is not dissolvable in the immersion medium.

28. The method of claim 21 wherein the protective film and the immersion medium have nearly matching indices of refraction.
